(19) United States
(12) Patent Application Publication
(10) Pub. No.: US 2007/0148794 A1
(43) Pub. Date: Jun. 28, 2007

(54) Method for designing a semiconductor device capable of reflecting a time delay effect for dummy metal fill

(75) Inventors: Wook Jin Cha, Seoul (KR); Nan Soon Choi, Incheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU ELECTRONICS CO., LTD.

(21) Appl. No.: 11/640,977

(22) Filed: Dec. 19, 2006

(30) Foreign Application Priority Data
Dec. 28, 2005 (KR) 10-2005-0131445

(51) Int. Cl. G06F 17/50; H01L 21/66; H01L 21/4763; G06F 9/45; G01R 31/26

(52) U.S. Cl. 438/14; 716/4; 716/6; 438/622

(57) ABSTRACT

Disclosed is a method for designing a semiconductor device. In an existing semiconductor design, a time delay effect caused by a dummy metal interconnection cannot be reflected. In order to address this disadvantage, a real metal fill pattern and a virtual metal fill pattern are employed for a layout parasitic extract step such that a time delay effect caused by the dummy metal pattern in semiconductor design is reflected. Accordingly, a semiconductor device can be designed by effectively reflecting a time delay effect. According to the method, since a real metal fill pattern and a virtual metal fill pattern are employed for a layout parasitic extract step so that resistor capacitance values of interconnections (including dummy interconnections) between logic elements are extracted, it is possible to more exactly design a semiconductor device by tacking a time delay effect into account.

### RELATED APPLICATION

This application claims the benefit of Korean Application No. 10-2005-0131445, filed on Dec. 28, 2005, which is incorporated by reference herein in its entirety.

### BACKGROUND

1. Technical Field

The present invention relates to semiconductor design technology. More specifically, the present invention relates to a method for designing a semiconductor device capable of effectively reflecting a time delay effect caused by dummy metal fill in a design procedure.

2. Description of the Related Art

Recently, as semiconductor manufacturing technology has been developed, line width has been rapidly reduced and the design complexity of semiconductor devices has relatively increased. Consequently, integrated circuits with several billion of transistors have been successively developed.

A semiconductor device is designed according to a logic synthesis flowchart shown in FIG. 1. Logic synthesis (see, reference numeral 10) in semiconductor design is where a designer uses a hardware description language (HDL) in designing a semiconductor device, at the system and circuit level. This is done instead of a circuit having a gate level design, as the complexity of very large-scale integration design (VLSI) for a digital circuit increases, and the demands for a quick time-to-Market increases.

In other words, through the logic synthesis, codes in the form of a register transfer level (RTL), which are models that may be realized as hardware, are automatically made into circuits at the gate level, comprising numerous logic gates, by using synthesis tools.

A placement & routing (P & R) step (step 20), which is the first step of the logic synthesis, automatically places and routes the automatically made logic gates, that is, cells having a transistor level (NMOS/PMOS). In this case, the placement is a way for placing gate cells, which have been already fabricated, in appropriate places of the inner part of a chip. The routing is important for connecting the placed gate cells to each other, thereby enabling the operation of the chips. Thus, since the placement & routing is complicated because of placing a great number of cells and connecting the cells to each other, the placement & routing is often performed by computer-aided design (CAD).

A layout parasitic extract step (step 30), which is the second step of the logic synthesis, extracts values for resistor capacitance (RC) of an interconnection between logic elements if the placement and routing for cells is completed in the P & R. Since the resistor capacitance value for the interconnection is closely related to a time delay, a resistor capacitance extract value is required in order to completely operate a circuit. To this end, a StarRCXT tool, which is a tool used for extracting resistor capacitance, is used.

Thereafter, a static timing analysis step (step 40), which is the third step of the logic synthesis, and a final GDSII layout versus schematic/design rule checker check step (step 40a), which is step 3a of the logic synthesis, are simultaneously performed.

A static timing analysis step (step 40), which is the third step of the logic synthesis, determines whether or not a chip operates in a desired specification (a frequency of 100 Mhz) based on information about resistor capacitance of the chip in order to rout and place logic cells and analyze timing of the logic cells.

Generally, it is determined whether a desired output corresponds to an input vector in order to perform simulation. However, since this determination is time consuming, only a flip-flop is determined in a logic without inputting an input vector, which is called the static timing analysis (step 40). The static timing analysis (step 40) may shorten the determination time by a factor of 10 since the input vector is not required. In this case, if the desired result is not the output. Instead, the procedure returns to the first step of the logic synthesis (step 10), and synthesis is repeated until the desired output results.

The GDSII LVS/DRC check step (step 40a), which is step 3a of the logic synthesis, checks a layout having the form of a GDSII, which is a format of design data used for creating a layout in order to fabricate a mask. This is done by using an LVS for determining whether or not the layout is exactly identical to a known circuitry and a DRC for verifying the semiconductor design layout.

Next is the mask generation for optical proximity correction (OPC) and metal fill pattern step (step 50), which is the fourth step of the logic synthesis. This step has two GDSII pattern forming sub-steps in order to ensure the yield rate and the stability of a manufacturing process when forming a mask. The first GDSII pattern forming sub-step forms a dummy interconnection pattern, that is, a metal fill pattern in an empty space of each interconnection layer such that each interconnection layer does not collapse during a chemical mechanical polishing (CMP) process. The second GDSII pattern forming sub-step is an OPC sub-step for correcting the shape of an edge of the interconnection in order to fabricate the interconnection having a clear shape.

The design of a mask used for forming a semiconductor device is completed through the steps of the logic synthesis (step 60). However, a manufacturing process employing a line width of 130 nm or less exhibits many phenomena which do not emerge in a manufacturing process employing a line width of 180 nm. Such phenomena occur due to the size of circuits, the reduction of a line width, and a low supply voltage. In particular, the reduction of the line width makes a time delay effect resulting from parasitic power capacitance important.

However, as shown in FIG. 1, according to the conventional logic synthesis, since the design of a semiconductor device is completed after the OPC and metal fill pattern forming step, the time delay effect cannot be reflected. In addition, a dummy metal interconnection must be filled in an area which has no metal interconnection, between a first metal interconnection layer to an eighth metal interconnection layer in order to perform a CMP process. At this time, a problem related to a time delay occurs.

In other words, as shown in FIG. 2, when performing a manufacturing process of a semiconductor device, metal interconnects 5 having a narrow interval therebetween are effectively etched, but metal interconnections 5a having a wide interval therebetween are over etched, so that the same layer is irregularly formed as shown in FIG. 3.

Since such a phenomenon reduces the yield rate of a semiconductor device, a dummy metal interconnection 6 must be filled in an area having no metal interconnection as shown in FIG. 4. However, if such a process is performed, since parasitic power capacitance 7 is created between signals (i.e., signals A and B) flowing through two metal interconnections having the dummy metal interconnection 6 therebetween as shown in FIG. 5, time delay between the signals A and B occurs.

Such problems may degrade the performance and the yield rate of a semiconductor chip as well as functions of the semiconductor chip. Although only the first metal interconnection layer is shown in FIG. 5, since many metal interconnection layers of the second metal interconnection layer to the eighth metal interconnection layer actually exist, many problems related to time delay occur. However, in the conventional design of a semiconductor device, it is difficult to take the problems occurring after the completion of semiconductor design into account.

### SUMMARY

The present invention has been made to solve the above problems occurring in the prior art. Therefore, consistent with the present invention, there is provided a method for designing a semiconductor device, capable of effectively reflecting a time delay effect caused by dummy metal fill in a design procedure by complementing a disadvantage of an existing semiconductor design scheme which cannot reflect the time delay effect caused by the dummy metal interconnection.

Further consistent with the present invention, there is provided a method for designing a semiconductor device through logic synthesis, the method comprising a placement and routing step for automatically placing and routing cells having a transistor level; a layout parasitic extract step of extracting a resistor capacitance value of an interconnection between logic elements after the placement and routing step; a static timing analysis step of determining, based on the resistor capacitance value, whether or not operation according to a desired specification is achieved after the layout parasitic extract step; a GDSII LVS/DRC check step of determining whether or not a layout is identical to a circuitry and verifying a layout of semiconductor design while performing the static timing analysis step; an OPC and metal fill pattern step of forming a metal fill pattern and complementing a shape of the metal fill pattern after the static timing analysis step and the GDSII LVS/DRC check step; a real metal fill pattern applying step of extracting a resistor capacitance value of an interconnection by employing the metal fill pattern formed in the OPC and metal fill pattern step for the layout parasitic extract step; and a step of performing the OPC and metal fill pattern step from the P & R step again by reflecting a time delay effect caused by the real metal fill pattern.

### BRIEF DESCRIPTION OF THE DRAWINGS

FIG. 1 is a flowchart showing a conventional logic synthesis procedure;

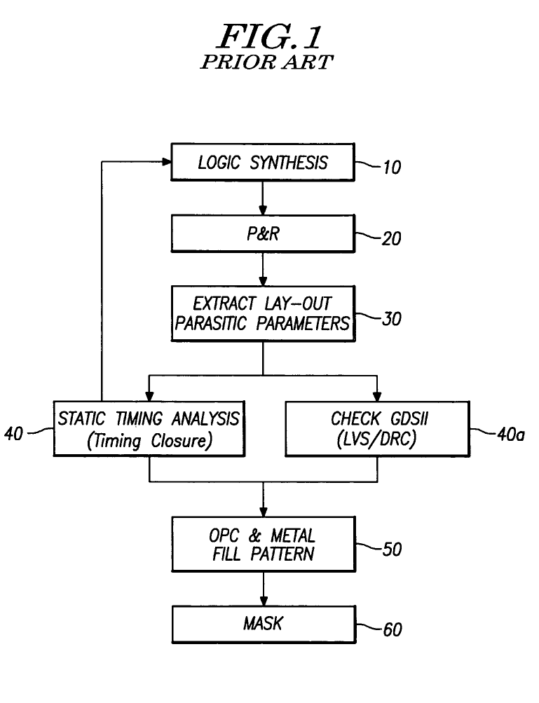

FIG. 2 is a view showing a conventional plasma etching degree according to the density of metal interconnections;

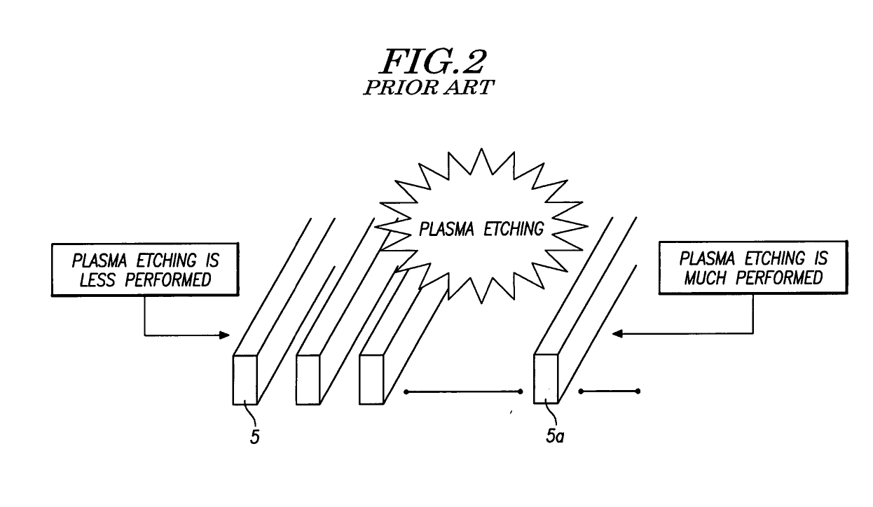

FIG. 3 is a sectional view showing a conventional metal interconnection layer irregularly formed;

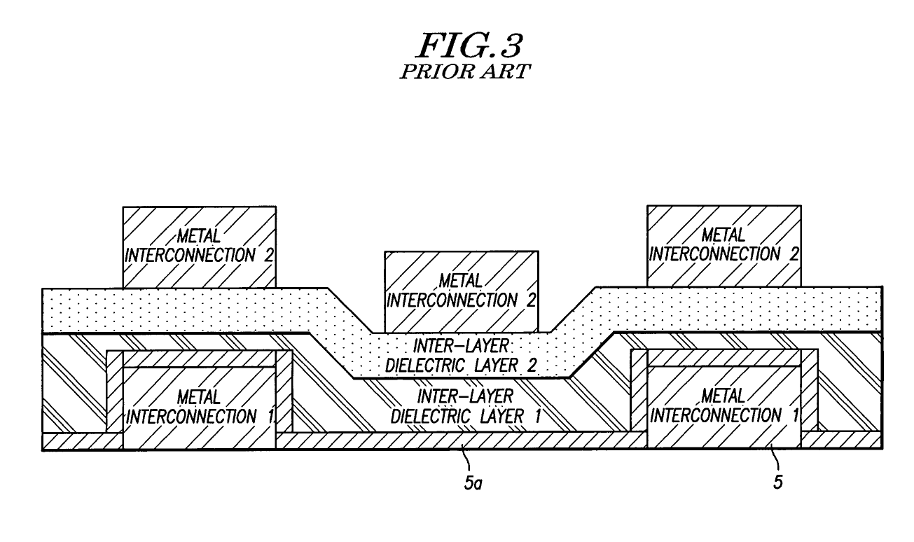

FIG. 4 is a sectional view showing a conventional metal interconnection layer uniformly formed by a dummy metal interconnection;

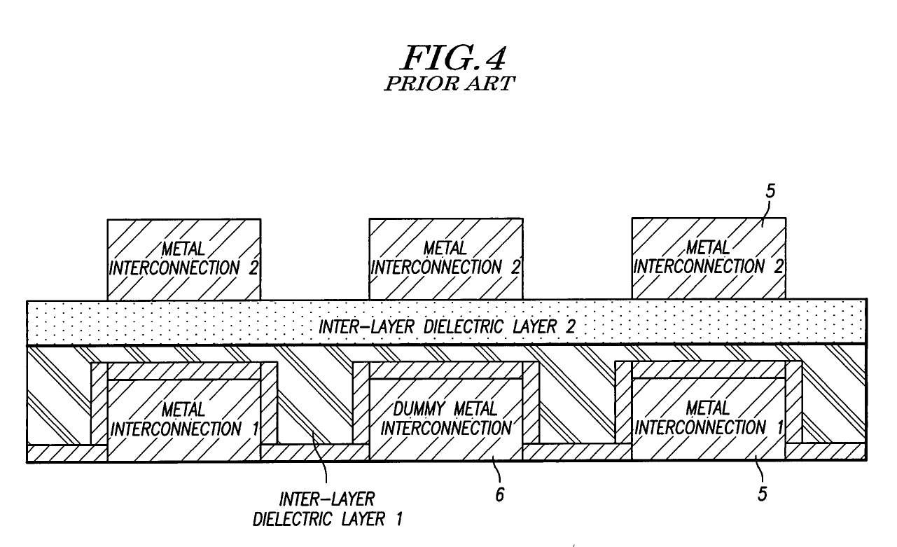

FIG. 5 is a view showing parasitic capacitance formed by a conventional dummy metal interconnection;

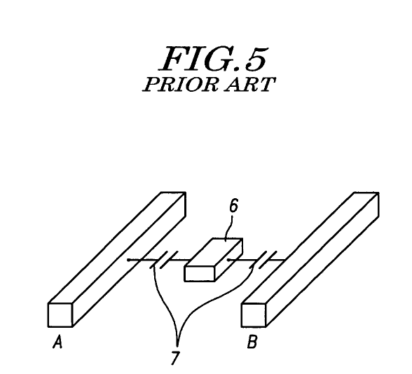

FIG. 6 is a flowchart showing a logic synthesis procedure according to a first embodiment consistent with the present invention; and

FIG. 7 is a flowchart showing a logic synthesis procedure according to a second embodiment consistent with the present invention.

### DETAILED DESCRIPTION

### Embodiment 1

Hereinafter, a first embodiment consistent with the present invention will be described with reference to the drawings.

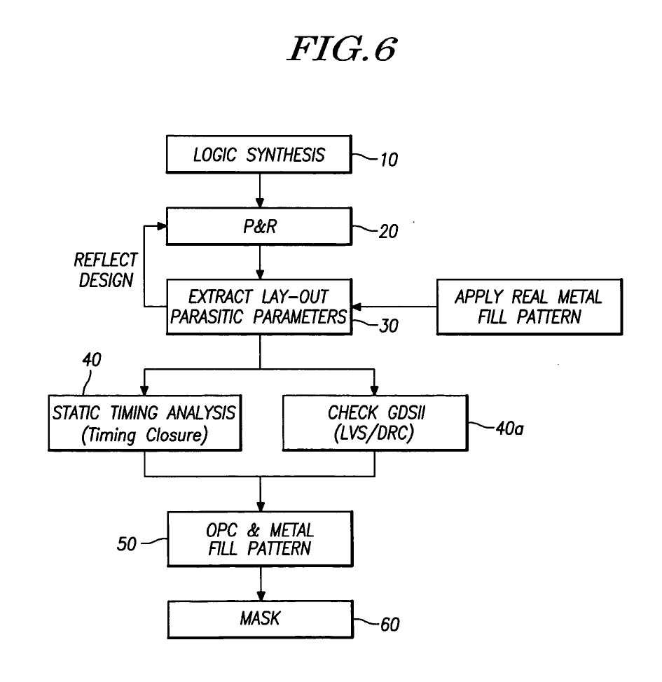

As shown in FIG. 6, a placement & routing (P & R) step (step 20), which is the first step of logic synthesis (see, reference numeral 10) in semiconductor design, automatically places and routes the automatically made logic gates, that is, cells at the transistor level.

Next, a layout parasitic extract step (step 30), which is the second step of the logic synthesis (see, reference numeral 10), extracts values for resistor capacitance (RC) of an interconnection between logic gates. Since the resistor capacitance value for the interconnection is closely related to a time delay, a resistor capacitance extract value is required in order to completely operate a circuit. To this end, a StarRCXT tool, which is a tool used for extracting resistor capacitance, is used.

Thereafter, a static timing analysis step (step 40), which is the third step of the logic synthesis, and a final GDSII layout versus schematic/design rule checker check step (step 40a), which is step 3a of the logic synthesis, are simultaneously performed.

The static timing analysis step (step 40), which is the third step of the logic synthesis, determines whether or not a chip operates in a desired specification (a frequency of 100 Mhz) based on information about resistor capacitance (RC) of the chip in order to rout and place logic cells and analyze timing of the logic cells.

Then, the GDSII LVS/DRC check step (step 40a), which is step 3a of the logic synthesis, checks a layout having the form of a GDSII by using an LVS for determining whether or not the layout is exactly identical to a circuitry and a DRC for verifying the semiconductor design layout.

Next, in a mask generation for optical proximity correction (OPC) and metal fill pattern step (step 50), which is the fourth step of the logic synthesis, a dummy interconnection pattern, that is, a metal fill pattern is formed in an empty space of each interconnection layer such that each interconnection layer does not collapse during a chemical mechanical polishing (CMP) process. In addition, an OPC step for correcting the shape of edges of patterns is used to fabricate the patterns having a clear shape.

A metal fill pattern, in which a dummy metal is inserted such that metal layers do not collapse, may be used. In other words, a real-metal fill pattern step is employed in the layout parasitic extract step (step 30), which is the second step of the logic synthesis (see, reference numeral 10). In this way, resistor capacitance values of interconnections (including dummy interconnections) between logic elements are extracted.

Next, logic gates, that is, cells at the transistor level are placed and routed in the P& R (step 20) step, by taking a time delay effect caused by a dummy metal into account. Thereafter, the second step to the fifth step of the logic synthesis are performed again, thereby completing the design of a mask.

Thus, if the real metal fill pattern is employed so as to extract resistor capacitance values, it is possible to more precisely design a semiconductor device in consideration of a time delay effect.

### Embodiment 2

Hereinafter, a second embodiment consistent with the present invention will be described with reference to the accompanying drawings.

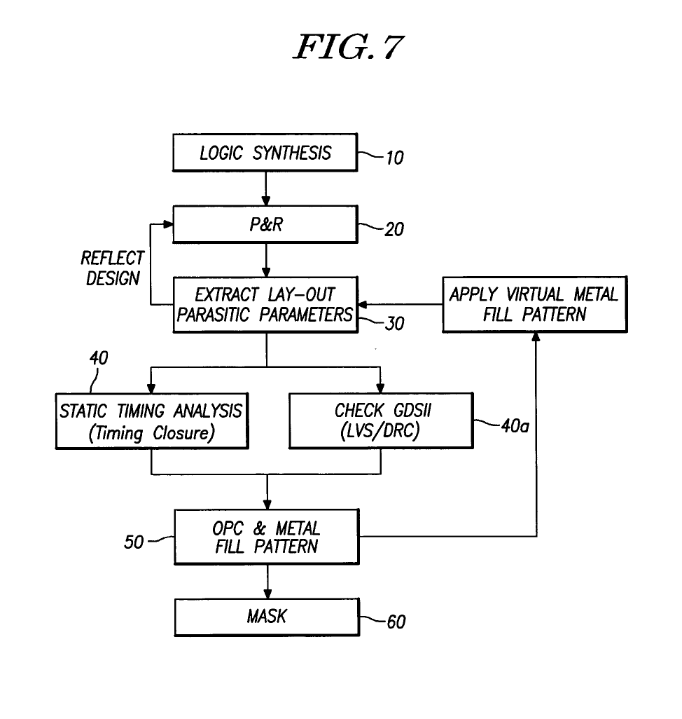

As shown in FIG. 7, in a placement & routing (P & R) step (step 20), which is the first step in logic synthesis (see, reference numeral 10), logic gates, that is, cells having a transistor level are placed and routed.

Next, in a layout parasitic extract step (step 30), which is the second step of the logic synthesis (see, reference numeral 10), values for resistor capacitance (RC) of an interconnection between logic elements are extracted. At this time, a virtual metal-fill pattern is fabricated based on information about an existing metal fill pattern having a defined interval between metal interconnections, and resistor capacitance values are extracted by using the virtual metal-fill pattern. In this case, a StarRCXT tool, which is a tool used for extracting resistor capacitance, is used.

Thereafter, logic gates, that is, cells at the transistor level are placed and routed in the P& R (step 20) step, by taking a time delay effect caused by a dummy metal into account.

Next, in a layout parasitic extract step (step 30), which is the second step of the logic synthesis (see, reference numeral 10), values for resistor capacitance (RC) of an interconnection between logic elements are extracted.

Thereafter, a static timing analysis step (step 40), which is the third step of the logic synthesis, and a final GDSII layout versus schematic/design rule checker check step (step 40a), which is step 3a of the logic synthesis, are simultaneously performed.

Next, in a mask generation for optical proximity correction (OPC) and metal fill pattern step (step 50), which is the fourth step of the logic synthesis, a dummy interconnection pattern, that is, a metal fill pattern, is formed in an empty space of each interconnection layer. This is done such that each interconnection layer does not collapse during a chemical mechanical polishing (CMP) process. In addition, an OPC step for correcting the shape of edges of patterns in order to fabricate the patterns having a clear shape is used, thereby completing the design of a mask (step 60).

Thus, according to a scheme of fabricating and considering a virtual metal fill pattern, it is possible to consider a time delay effect for a dummy metal interconnection in a semiconductor design while maintaining the degree of design accuracy as compared with a real metal fill pattern scheme.

In addition, different from a real-metal fill pattern scheme, the OPC and metal fill pattern step, step four, is not performed. In addition, a virtual metal fill pattern is fabricated and is directly applied to the layout parasitic extract step, which is the second step of the logic synthesis, in order to reduce time.

As described above, according to the present invention, since a real metal fill pattern is employed for a layout parasitic extract step so that resistor capacitance values of interconnections (including dummy interconnections) between logic elements are extracted, it is possible to design a semiconductor device with greater accuracy by taking a time delay effect into account.

In addition, consistent with the present invention, since a virtual metal fill pattern is fabricated based on information about an existing metal fill pattern and then employed for the layout parasitic extract step so that resistor capacitance values of interconnections (including dummy interconnections) between logic elements are extracted, it is possible to design a semiconductor device with greater accuracy by taking a time delay effect into account.

In addition, consistent with the present invention, differently from the real metal fill pattern scheme, a scheme of fabricating and considering a virtual metal fill pattern is employed, so that the OPC and metal fill pattern step is not necessary to be performed, but a virtual metal fill pattern is fabricated and directly applied to the layout parasitic extract step, which is the second step. Accordingly, it is possible to reduce the time required for semiconductor design.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for designing a semiconductor device through logic synthesis, the method comprising:
a placement and routing step for automatically placing and routing transistor level cells;
a layout parasitic extract step of extracting a resistor capacitance value of an interconnection between logic elements after the placement and routing step;
a static timing analysis step of determining, based on the resistor capacitance value, whether or not an operation according to a desired specification is achieved after the layout parasitic extract step;
a GDSII LVS/DRC check step of determining whether or not a layout is identical to an expected circuitry and verifying a layout of semiconductor design while performing the static timing analysis step;
an OPC and metal fill pattern step of forming a metal fill pattern and complementing a shape of the metal fill pattern after the static timing analysis step and the GDSII LVS/DRC check step;
a real metal fill pattern applying step of extracting a resistor capacitance value of an interconnection by employing the metal fill pattern formed in the OPC and metal fill pattern step for the layout parasitic extract step; and
a step of performing the OPC and metal fill pattern step from the placement and routing step again by reflecting a time delay effect caused by the real metal fill pattern.

2. The method as claimed in claim 1, wherein the resistor capacitance value is extracted by using a starRCXT tool, which is a resistor capacitance extracting tool, in the layout parasitic extract step.

3. A method for designing a semiconductor device through logic synthesis, the method comprising:
a placement and routing step for automatically placing and routing transistor level cells;
a layout parasitic extract step of fabricating a virtual metal fill pattern and extracting a resistor capacitance value of an interconnection between logic elements after the placement and routing step;
a static timing analysis step of determining based on the resistor capacitance value whether or not operation according to a desired specification is achieved after the layout parasitic extract step;
a GDSII LVS/DRC check step of determining whether or not a layout is identical to an expected circuitry and verifying a layout of semiconductor design while performing the static timing analysis step; and
an OPC and metal fill pattern step of forming a metal fill pattern and complementing a shape of the metal fill pattern after the static timing analysis step and the GDSII LVS/DRC check.

4. The method as claimed in claim 3, wherein the resistor capacitance value is extracted by using a starRCXT tool, which is a resistor capacitance extracting tool, in the layout parasitic extract step.
